(19) United States
(12) Patent Application Publication
(10) Pub. No.: US 2011/0167913 A1
(43) Pub. Date: Jul. 14, 2011

(54) IMAGING DEVICES FOR MEASURING THE STRUCTURE OF A SURFACE

(75) Inventors: Mark Joseph Bennahmias, Ladera Ranch, CA (US); Michael John Zani, Laguna Niguel, CA (US)

(73) Assignee: NEXGEN SEMI HOLDING, INC., Laguna Niguel, CA (US)

(21) Appl. No.: 12/905,841

(22) Filed: Oct. 15, 2010

Related U.S. Application Data
(60) Provisional application No. 61/252,058, filed on Oct. 15, 2009.

(51) Int. Cl. G01N 29/04; H05K 13/04

(52) U.S. Cl. 73/606; 29/592.1

(57) ABSTRACT

Imaging devices for measuring a structure of a surface and methods of use are provided. In certain embodiments, an imaging device includes at least one nano-mechanical resonator pair. The pair includes a reference resonator having a reference resonant frequency, and a sense resonator having a first sense resonant frequency. The device is configured to expose the sense resonator to the surface such that the sense resonator has a second sense resonant frequency. The device is also configured to measure the structure of the surface based on a difference between the second sense resonant frequency and the reference resonant frequency. In certain embodiments, an imaging device for measuring the structure of a surface includes an array of sense nano-electromechanical resonators. In certain embodiments, the array of single nano-electromechanical resonators is advantageously arranged in a staggered configuration.

### CLAIM OF PRIORITY

The present application claims the benefit of priority to U.S. Provisional Patent Application No. 61/252,058, filed on Oct. 15, 2009, and incorporated in its entirety by reference herein.

### BACKGROUND

1. Technical Field

This application relates generally to imaging devices for measuring the structure of a surface, and more particularly, to a high fidelity, high resolution, high signal to noise ratio, high speed imaging device for mapping large surfaces of semiconducting and biological materials. Imaging applications include semiconductor circuit defect analysis, tamper detection, biological imaging, and characterization of superconducting and magnetic materials.

2. Description of the Related Art

As the methods of manufacturing nanotechnology mature, the ability to image small nanoscale features can to involve radically innovative approaches using nanotechnology itself namely “using atoms to see other atoms”. For example, the advancement made in the last several years in the microelectronics industry is astonishing principally owing success to scalability. As things became smaller, the underlying physical principles did not change much. New steps in technology, built on previous knowledge, and financed by profits from sales of the previous generation of such technology was an ongoing non-disruptive development environment. However, beyond today's 22 nm technology node, a real issue arises as to how to take the transistor size down below 11 nm, for which entirely new enabling manufacturing concepts accompanied by next generation imaging and diagnostic tools can become critical.

Some say that a metrology infrastructure has underpinned all industrial revolutions. Efficient mass production can depend on a reliable means for manufacturing process control. In turn, it is important to have the means for rapid and inexpensive measurement of critical manufacturing parameters. These fundamental considerations are also important in nanotechnology. For example, it is important in manufacturing of circuits with 11 nm critical dimensions (CD) to have a metrology infrastructure capable of rapid measurement of the size and location of features to an accuracy of ˜20% of the CD, or 2 nm. It is advantageous for next generation imaging tools to have the capability for sub-nm resolution to achieve sufficiently high signal-to-noise performance in order to support circuit editing, fault isolation, and logic analysis.

Such analysis and imaging technology is frankly nonexistent, and the current diagnostic toolkit seems wholly inadequate for the task and therefore a real bottleneck in terms of image acquisition speed and meeting resolution and reliability targets of future technology nodes. The next generation of nanotechnology industries faces dimensional measurement and characterization challenges that far exceed the present limits of measurement science. The manufacturing paradigm at this scale is rapidly being transformed by major advances in self-assembly, bio-manufacturing, massively parallel atomically-precise manufacturing, and next generation maskless, resistless semiconductor tools.

It is important to consider rethinking of the methods and application of measurement science to manufacturing as incremental improvements of existing methods seem to be inadequate. For example, it is important to measure nanometer-scale features in complex three-dimensional semiconducting and biological shapes with unprecedented precision and uncertainty, and with extremely high throughput.

### SUMMARY

Imaging devices for measuring a structure of a surface and methods of use are provided. In certain embodiments, an imaging device includes at least one nano-mechanical resonator pair. The pair includes a reference resonator having a reference resonant frequency, and a sense resonator having a first sense resonant frequency. The device is configured to expose the sense resonator to the surface such that the sense resonator has a second sense resonant frequency. The device is also configured to measure the structure of the surface based on a difference between the second sense resonant frequency and the reference resonant frequency. In certain embodiments, the at least one nano-mechanical resonator pair includes a plurality of nano-resonator pairs.

In certain embodiments, an imaging device for measuring the structure of a surface includes a sensor. The sensor includes at least one sense nano-electromechanical resonator. In certain embodiments, the sense resonator is suspended over a support platform via support posts. In certain embodiments, an imaging device is provided where the imaging device includes an array of these at least one sense nano-electromechanical resonators. In certain embodiments, the array of single nano-electromechanical resonators is advantageously arranged in a staggered configuration.

### BRIEF DESCRIPTION OF THE DRAWINGS

FIG. 1A schematically illustrates an example imaging device for measuring the structure of a surface in accordance with certain embodiments described herein.

FIG. 1B schematically illustrates an example imaging device being scanned over a material surface under test in accordance with certain embodiments described herein.

FIG. 2 schematically illustrates an example imaging device being scanned over a surface in accordance with certain embodiments described herein.

FIG. 3 schematically illustrates an example method of inducing a resonant frequency in the resonator pairs in accordance with certain embodiments described herein.

FIGS. 4A and 4B schematically illustrate example imaging devices being scanned over a surface in accordance with certain embodiments described herein.

FIG. 5 schematically illustrates an example imaging device for measuring the structure of a surface in accordance with certain embodiments described herein.

FIG. 6 schematically illustrates an example imaging device for measuring the structure of a surface in accordance with certain embodiments described herein.

FIGS. 7A-7B schematically illustrate example imaging devices for measuring the structure of a surface in accordance with certain embodiments described herein.

FIGS. 8A-8F schematically illustrate the steps in an example method of producing a sensor array in accordance with certain embodiments described herein.

FIG. 9 is an example measurement system compatible with certain embodiments described herein.

FIG. 10 schematically illustrates an example array of resonators in accordance with certain embodiments described herein.

FIG. 11 is an example circuit compatible with certain embodiments described herein.

### DETAILED DESCRIPTION

In imaging the atomic structure of semiconducting and biological materials, the inventors have realized that the limitations of conventional imaging methods as described in Table 1 can be overcome with certain embodiments disclosed herein. For example, certain embodiments disclosed herein are directed to a high resolution, high signal to noise ratio, and high speed imaging devices.

TABLE 1
A brief list of conventional imaging methods available
and their associated resolution and limitations

| | | Resolution | |
|---|---|---|---|
| | Data | Lateral (nm) | |
| Type | Type | Depth (nm) | Issues / Limitations |
| AFM | 3D | 2-3 | Spatial resolution limited by size and shape of probe tip |
| | | 0.5-5 | Very long image acquisition times for large areas while |
| | | | meeting resolution |
| | | | Low tip manufacturing yields |
| | | | Eventual wearing of tip |
| SEM | 2D | 1-20 | Non-metalic samples require metallic sputtering |
| | | 1-5000 | Inverse Lambertian reflectance |
| | | | Limits on resolution due to secondary electron yield |
| | | | Higher beam energies makes it difficult to resolve surface |
| | | | detail |
| | | | Hydrocarbon deposits on samples |
| TEM | 2D | 2-20 | Demanding sample preparation |
| | | 200 | Requires cross-sectioning devices reducing circuit |
| | | | functionality |
| | | | Low signal-to-noise ratio |
| Optical | 3D | 50-100 | Samples must not be completely transparent to light |
| | | 1-5 | wavelength |
| | | | Resolution limited by diffraction phenomenon |

Recent demonstration (see e.g., J. S. Bunch et al., “Electromechanical Resonators from Graphene Sheets,” Science, Vol. 315, no. 5811, pp. 490-3 (2007) and D. Garcia-Sanchez et al., “Imaging Mechanical Vibrations in Suspended Graphene Sheets,” Nano Letters, Vol. 8, pp. 1399-1403 (2008)) has shown that a properly designed nano-electromechanical sensor (NEMS) (see e.g., C. Chen et al., “Performance of Monolayer Graphene Nanomechanical Resonators with Electrical Readout,” Nature Nanotechnology 4 (2009) and W. Bao et al., “Ripple Texturing of Suspended Graphene Atomic Membranes,” Nature Nanotechnology 4, pp. 562-566 (2009)) such as a doubly clamped suspended cantilever of single layer Graphene (SLG) with nanoscale dimensions for example can be highly sensitive at room temperature to detect small variations in surface atomic forces (e.g., about 1 fN/Hz^{1/2}) corresponding to a detection threshold of charge variation on a biological or semiconducting material surface approaching single electrons, rivaling the performance of Radio Frequency (RF) single electron transistor electrometers.

Exhibiting high Young's modulus, extremely low mass, and large surface area, nanoscale resonators are ideally suited for use in many types of applications related to atomic scale mass, force, field, and charge measurements. NEMS devices can be excited and driven into oscillatory motion by thermal, electric, magnetic, or optical means to induce specific vibration and torsion modes in a controlled manner with resonant frequencies (e.g., tens of MHz) depending upon the shape and geometry of the nanoscale resonator architecture and the materials used to fabricate them. This resonance behavior can be modified (e.g., about a few nm in amplitude, about 10's degrees in phase, and about tens of MHz in frequency) in a deterministic fashion by placing a NEMS device architecture designed to show high sensitivity to one or more specific environmental factors like heat, strain, stress, pressure, atomic composition, electric fields, and magnetic fields into these environments.

The unique properties of NEMS with excellent room temperature charge sensitivity (e.g., about 1e⁻⁴ e/Hz^{1/2}) and reasonably high Q-Factors (e.g., about 100; see, e.g., J. S. Bunch et al., “Electromechanical Resonators from Graphene Sheets,” Science, Vol. 315, no. 5811, pp. 490-3 (2007)) suggest they could also be used as excellent diagnostic tools for semiconductor circuit analysis, to map minute surface variations in local electrostatic field distributions to identify with high accuracy the location of embedded defects like vacancies and impurities as the sensor is scanned over a surface under test (SUT) or to obtain high fidelity imagery (contrast, gain, signal-to-noise ratio) of biological specimens by sensing and recording minute changes in magnetic fields due to electron migration. NEMS devices exhibit resolution and imaging performance similar to a traditional AFM instrument yet operated in a non-contact mode avoiding the typical mechanical wear and calibration issues associated with scanning AFM tips.

In a similar fashion to what is currently performed with raw image data collected by AFM instrumentation, the signal data collected from an analogous NEMS sensor can be processed using advanced surface reconstruction algorithms to form a quality image of a material surface. Since the dimensions of these NEMS devices can be made very small (e.g., on the order of a few nm width and 10's of nm in length) the spatial resolution for discerning nanoscale features in the morphology of a SUT is on par with what is available with an AFM.

Similar to present day practice for monitoring the motion of the cantilever action of an AFM tip the changes to the oscillatory signals produced by the NEMS device as it is scanned in close proximity in non-contact operation over a SUT can be monitored through a number of different readout methods including mechanical, electrical, and optical.

Unfortunately as the physical size of a biological specimen of interest becomes larger or there is a desire to measure an entire semiconductor die (e.g., about 1 cm²), the use of a conventional AFM or NEMS based instrument demands very long acquisition times, taking on the order of a few days, or weeks to complete, to produce high quality image reconstructions over the full image field and therefore not of great practical use to support high volume semiconductor manufacturing. As disclosed herein, the spatial resolution of certain embodiments described herein is not limited by the size and shape of a probe tip. Additionally, certain embodiments described herein improve the image acquisition times for large areas while meeting resolution.

Certain embodiments as will be described further below include a single resonator architecture or a multiple resonator architecture. Some embodiments employ the use of at least one common reference resonator. Others include a pair of matched resonators wherein one resonator acts as a local reference and the other resonator as the sensing element. Certain embodiments include a plurality of single resonator architecture or a multiple resonator architecture. The plurality in certain embodiments can be arranged in an array configuration.

Certain embodiments disclosed herein are directed to a high resolution imaging device for measuring the atomic structure of a surface using a pair of nano-mechanical resonator pairs. One of the resonators is a reference resonator and the other is a sense resonator. In certain embodiments, each of the resonators of the resonator pair can be first balanced with a laser so that they are tuned to each other to resonate at the substantially the same frequencies. To operate the imaging device, the sense resonator is scanned over the material surface under test, while the reference resonator is isolated from it. The atomic forces from the surface are applied to the sense resonator, thereby changing the resonant frequency of the sense resonator but not of the reference resonator. A laser interferometer can then be used to measure the difference between this changed resonant frequency of the sense resonator and the unchanged resonant frequency of the reference resonator. The measured difference can then provide the image of the structure of the material surface.

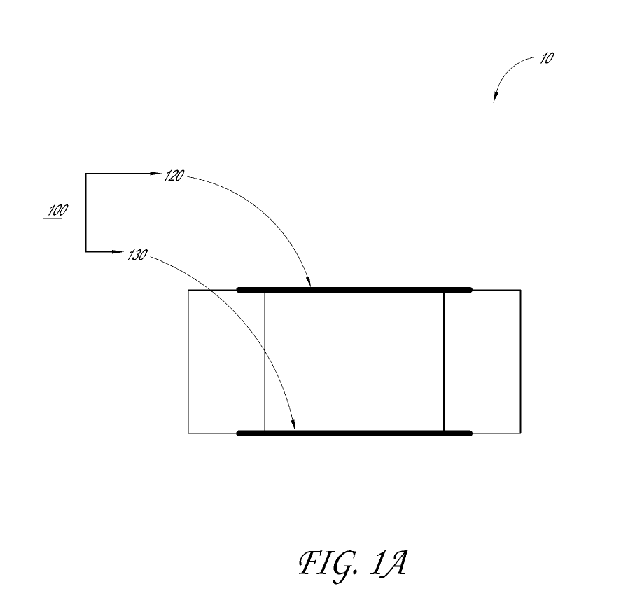

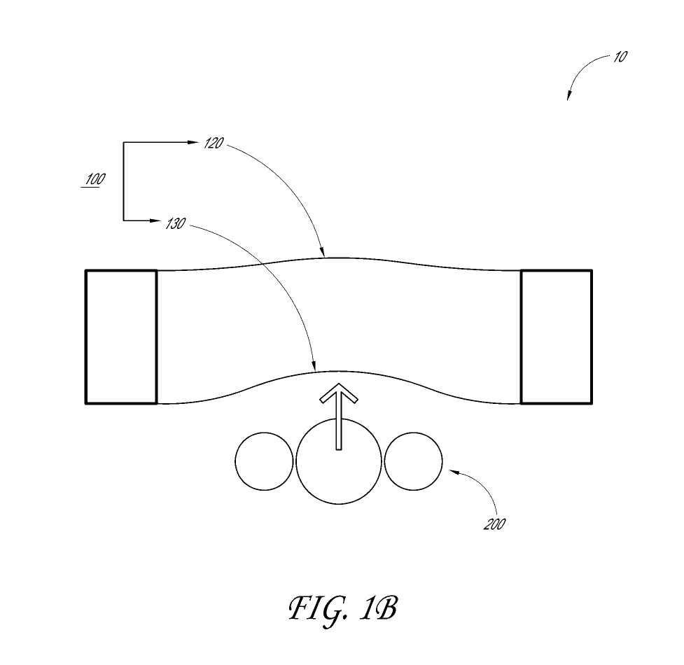

FIG. 1A schematically illustrates an example imaging device 10 for measuring the structure of a surface in accordance with certain embodiments described herein. The imaging device 10, for example, could measure the atomic structure of a surface. The imaging device 10 includes at least one nano-mechanical resonator pair 100. This resonator pair 100 can form the imaging head which is scanned over the structure of a surface. The resonator pair 100 includes a reference resonator 120 having a reference resonant frequency, and a sense resonator 130 having a first sense resonant frequency. As shown in FIG. 1B, the imaging device 10 in FIG. 1A is configured to expose the sense resonator 130 to the surface 200 under test such that the sense resonator 130 has a second sense resonant frequency. The sense resonator 130 can be displaced along the surface 200 under test over time while scanning. The imaging device 10 is configured to measure the structure of the surface 200 based on a difference between the second sense resonant frequency and the reference resonant frequency.

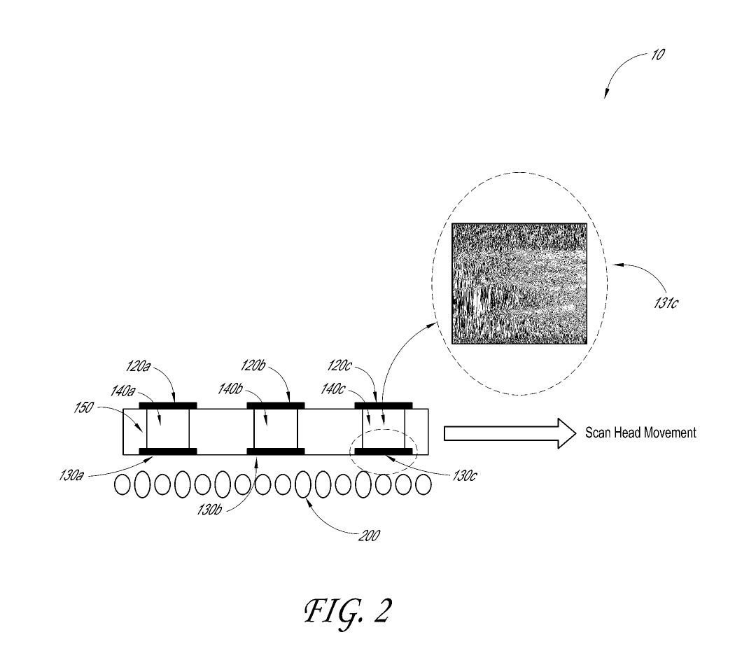

FIG. 2 schematically illustrates an example embodiment of imaging device 10 being scanned over the surface 200 of a material. Certain embodiments of the imaging device 10 can include a plurality of nano-mechanical resonator pairs 120a and 130a, 120b and 130b, 120c and 130c. These embodiments advantageously reduce data acquisition times. In the embodiment shown in FIG. 2, the plurality of resonator pairs 120a and 130a, 120b and 130b, 120c and 130c are arranged in a linear array. Other arrangements are possible. For example, the array could be configured in a staggered configuration, in multiple geometric orientation along a 2D plane, in multiple geometric orientation along the axial 3D coordinate, etc.

In certain embodiments, each sense resonator 130a 130b 130c can include a sense ribbon 131a 131b 131c (within 130a 130b 130c). In certain embodiments, a sense resonator, e.g., 130c, and a sense ribbon, e.g., 131c, are the same. In other embodiments, a sense resonator, e.g., 130c, includes a separate sense ribbon, e.g., 131c. Although the term “ribbon” is used, other structures are possible. For example and without limitation, the structure may be a nano-beam, nano-ribbon, nano-tube, singly clamped cantilever, doubly clamped cantilever, nanowire, nano-coil, annular 2D structure, 2D rectangular structure, 2D circular structure, 2D elliptical structure, 2D hexagonal structure, 3D tetrahedral structure, 3D cylindrical structure, 3D spherical structure, 3D pyramid structure, 2D polygonal structure, etc. In certain embodiments, the structures are the same. In other embodiments, the structures are different. In certain embodiments, the structures are physical structures. In certain embodiments, structure includes an array of mini structures.

In certain embodiments, each sense ribbon 131a 131b 131c can include graphene. An example of a resonating graphene ribbon 131c is shown in FIG. 2. As disclosed above, graphene has advantageous characteristics. In certain embodiments, a person skilled in the art would recognize that other resonating materials can be used. For example, the material could include Aluminum Molybdenum alloys, Magnetic thin films, Piezoelectric thin films, Silicon, Gallium Arsenide, Silicon Dioxide, Graphene Oxide, Graphite, Graphane, Silicon Carbide, Lead Selenide, Zinc Oxide, Titanium Dioxide, Vanadium Oxide, Boron Nitride, Titanium Nitride, Bismuth Selenium, Calcium Sulfide, Bismuth Oxychloride, Bismuth Vanadate, Niobium Nitride, and Niobium Oxide.

Similar to the sense resonators 130a 130b 130c, in certain embodiments, each reference resonator 120a 120b 120c can include a reference ribbon 121a 121b 121c (within 120a 120b 120c). In certain embodiments, a reference resonator, e.g., 120c, and a reference ribbon, e.g., 130c, are the same. In other embodiments, a reference resonator, e.g., 120c, includes a separate reference ribbon, e.g., 121c. Similar to the sense ribbons 131a 131b 131c, each reference ribbon 121a 121b 121c can also include graphene or other materials as listed above. Also, as explained for the sense resonators, other structures are possible.

Also as shown in the embodiment of FIG. 2, each reference ribbon 120a 120b 120c and each sense ribbon 130a 130b 130c can be suspended over trenches 140a 140b 140c on a substrate 150. In certain embodiments the trenches 140a 140b 140c are patterned. Fabrication techniques known in the art or yet to be devised can be utilized. Certain fabrication techniques are discussed further below. In certain embodiments, both ends of each reference ribbon 120a 120b 120c can be clamped on both ends to the substrate 150. Likewise, in certain embodiments, both ends of each sense ribbon 130a 130b 130c can be clamped on both ends. In embodiments of different nanomechanical structures, the nanomechanical structures can be secured on two or more ends.

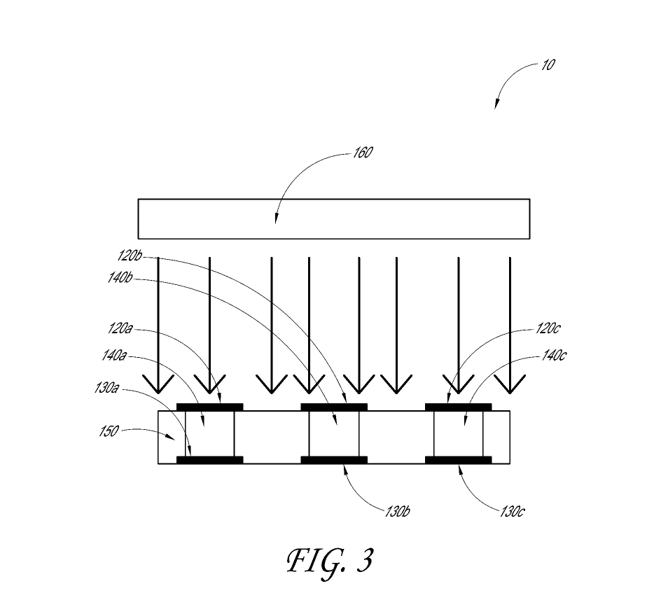

FIG. 3 schematically illustrates an example method of inducing a reference resonant frequency in each of the plurality of reference resonators 120a 120b 120c and of inducing a first sense resonant frequency in each of the plurality of sense resonators 130a 130b 130c. For example, a laser 160 could be used to thermally excite by laser heating each of the reference ribbons 121a 121b 121c (within 120a 120b 120c) and each of the sense ribbons 131a 131b 131c (within 130a 130b 130c). The laser 160 can introduce a prescribed amount of thermal strain mismatch between the physical shape and geometry of the ribbons, e.g., 121a 121b 121c 131a 131b 131c, the substrate 150 material of the walls of the trenches 140a 140b 140c, and the material used to clamp the ends down. The thermal strain mismatch induces vibration at a resonant frequency. In certain embodiments, the reference resonant frequency for each of the reference ribbons 121a 121b 121c and the first sense resonant frequency for each of the sense ribbons 131a 131b 131c can be advantageously pre-determined. In some embodiments as shown in FIG. 3, a reference resonator, e.g., 120a, and a sense resonator, e.g., 130a, can be balanced so that they are tuned to each other and resonate at substantially the same frequency. In these embodiments, the first sense resonant frequency is substantially the same as the reference resonant frequency. In other embodiments, a reference resonator, e.g., 120a, and a sense resonator, e.g., 130a, can be balanced so that they are tuned to each other but resonate at different frequencies. For simplicity, the disclosure described herein will focus on a first sense resonant frequency substantially the same as the reference resonant frequency. However, a person skilled in the art would realize that in embodiments where the reference resonant frequency of the reference resonator, e.g., 120a, and the first sense resonant frequency of the sense resonator, e.g., 130a, are different, the difference can be accounted for when measuring the structure of a surface.

In certain embodiments, other ways to excite the ribbons are used. For example, the ribbons could be excited by an electric field, a gravitational field, a gradational field, a magnetic field, a phonon, light, temperature, physical contact, etc.

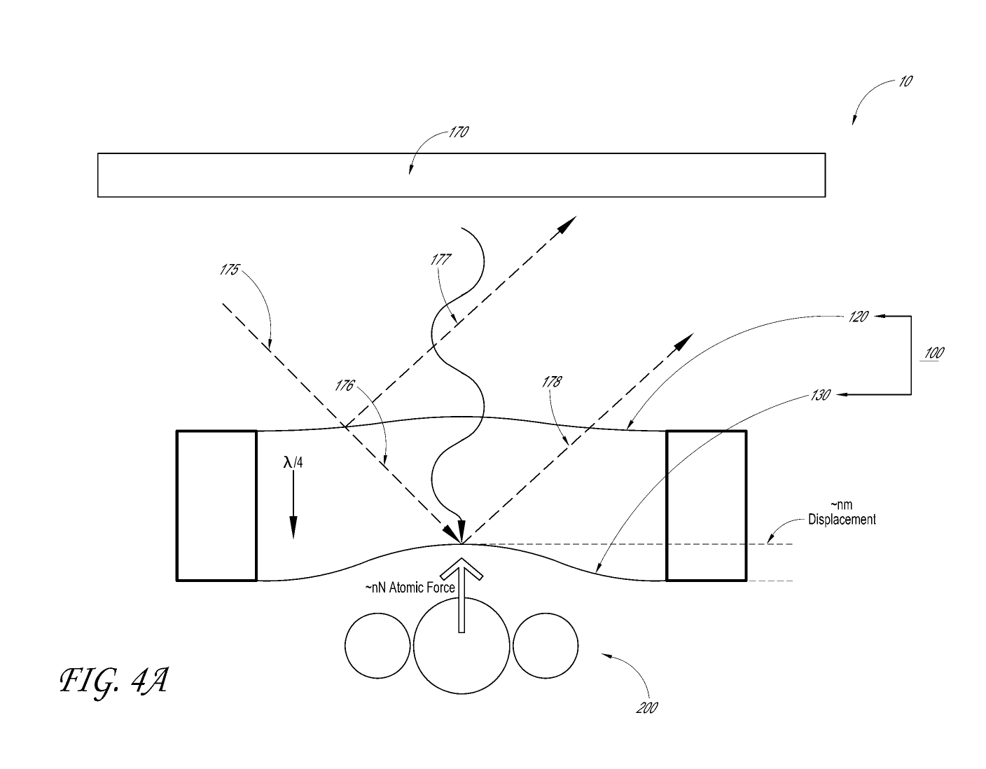

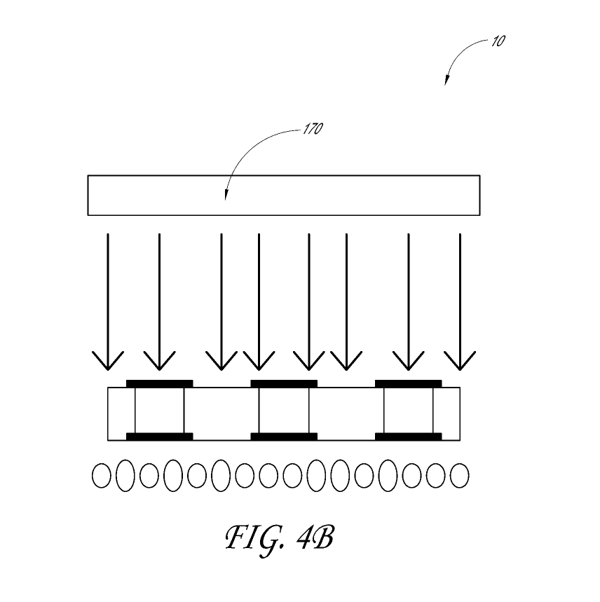

FIG. 4A provides some typical physical scaling values for a resonator pair 100 of an example image device 10 scanned over a surface 200. A single imaging element, which includes a reference resonator 120 and a sense resonator 130, of the imaging device 100 is shown. As shown in FIG. 4A, the imaging device 10 is configured to expose the sense resonator 130 to the surface 200 to forces at the material surface 200 under test. FIG. 4A shows the loading by local surface forces, e.g., atomic forces. In certain embodiments, the imaging device 10 is configured to isolate the reference resonator 120 from the surface 200 under test. In certain embodiments where sense resonator 130 is exposed to the surface 200, while the reference resonator 120 is isolated from the surface 200, the reference resonant frequency remains substantially the same. However, the resonant frequency of the sense resonator 130 can change such that it becomes a second sense resonant frequency different from the first sense resonant frequency.

For example, as the imaging head is slowly scanned over the material surface 200 under test, local atomic forces apply additional stress loading, as shown in FIG. 4A, to the sense resonator 130. This de-tunes the oscillation frequency of the sense resonator 130 relative to the reference resonator 120. Thus, certain embodiments of the imaging device 10 is configured to measure the structure 200 based on a difference between the second sense resonant frequency and the reference resonant frequency. In certain embodiments, the applied forces could be derived by an electric field, a gravitational field, a gradational field, a magnetic field, phonons, light, temperature, physical contact, etc.

In certain embodiments as shown in FIGS. 4A and 4B, the imaging device 10 can comprise a laser interferometer 170 to measure the difference between the second sense resonant frequency and the reference resonant frequency. The laser interferometer 170 in certain embodiments, as shown in FIG. 4A, can transmit a first light 175 incident on the reference resonator 120 and a second light 176 incident on the sense resonator 130. In these embodiments, the reference resonator 120 is configured to reflect a portion of the first light 177 having a first phase and a first optical path. The sense resonator 130 is configured to reflect a portion of the second light 178 having a second phase and a second optical path. In certain embodiments, the laser interferometer 170 can record an interference pattern resulting from the combination of the reflected portion of the first light 177 and the reflected portion of the second light 178. The interference pattern can include resultant light and dark fringes. The resultant light results from constructive interference when the reference resonant frequency of the reference resonator 120 and second sense resonant frequency of the sense resonator 130 are not matched. The dark fringes result from destructive interference when the reference resonant frequency of the reference resonator 120 and the second sense resonant frequency of the sense resonator 130 are matched.

In certain embodiments, the laser interferometer 170 records the interference pattern at a different fundamental wavelength than used to initially excite the mechanical resonance of the cantilevers, e.g., the reference resonant frequency of the reference resonator 120 and the first sense resonant frequency of the sense resonator 130.

With optical readout of the imaging head, the change in frequency is monitored by measuring the change in phase or optical path difference of the reflected light from each of the resonating layers in the pair. The resonating mode of the sense resonator 130 can be different than the reference resonator 120 in both frequency and amplitude when exposed to surface atoms so that a detectable time varying differential optical signals is produced. For example, in certain embodiments, the difference between the second sense resonant frequency and the reference resonant frequency can be measured by measuring a difference between the second phase and the first phase. In certain embodiments, the difference between the second sense resonant frequency and the reference resonant frequency can also be measured by measuring a difference between the second optical path and the first optical path.

In certain embodiments, the difference between the second sense resonant frequency and the reference resonant frequency can involve an electrical measurement. For example, in certain embodiments, a first electrical excitation signal is applied on the reference resonator and a second electrical signal is applied on the sense resonator. The difference between the second sense resonant frequency and the reference resonant frequency is measured by comparing a portion of the first signal having a first phase and a first amplitude; and a portion of the second signal having a second phase and a second amplitude. The device can record, e.g., a Lissajous figure pattern, which is a combination of the phases and amplitudes of the signals. In certain embodiments, the difference between the second sense resonant frequency and the reference resonant frequency is measured by measuring a difference between the second phase and the first phase. In other embodiments, the difference between the second sense resonant frequency and the reference resonant frequency is measured by measuring a difference between the second amplitude and the first amplitude.

The sensitivity of pico-Newton to nano-Newton atomic forces can be directly dependent on the optimized shape and geometry of the nano-beams of the sense resonator 130. In embodiments where the scan head includes an array of the nano-scale parallel sensing elements as described herein, the imaging of a wide area, e.g., about 1 cm² can be performed with high resolution (e.g., about 1-100 nm, about 0.1-10 nm, about 0.1-5 nm, about 2-3 nm, about 0.1-1 nm), with high sensitivity (e.g., 10's pN to a few nN, about 100 pico-Newtons, about 10 pico-Newtons, about 1 pico-Newton, about 0.1 pico-Newton), and can be performed much quicker (e.g., 1 cm² in several seconds) than is possible using a conventional atomic force microscope (AFM).

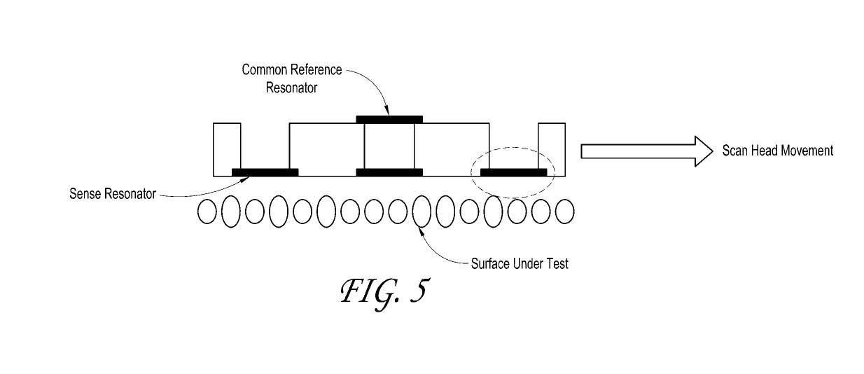

In certain embodiments of the imaging device 10 as disclosed herein, the number of sense resonators 130 are equal to the number of reference resonators 120. In other embodiments, it may be advantageous to reduce the number of reference resonators 120 such that the number of reference resonators 120 is less than the number of sense resonators 130. For example, the embodiment disclosed in FIG. 5 employs a common reference resonator for the entire array of sense resonators.

In further embodiments as will be described below, the imaging device 10 may have no reference resonators 120. In certain embodiments, the imaging device senses local environmental interactions by measuring changes in, e.g., conductivity caused by changes in tension within the nano-resonator material.

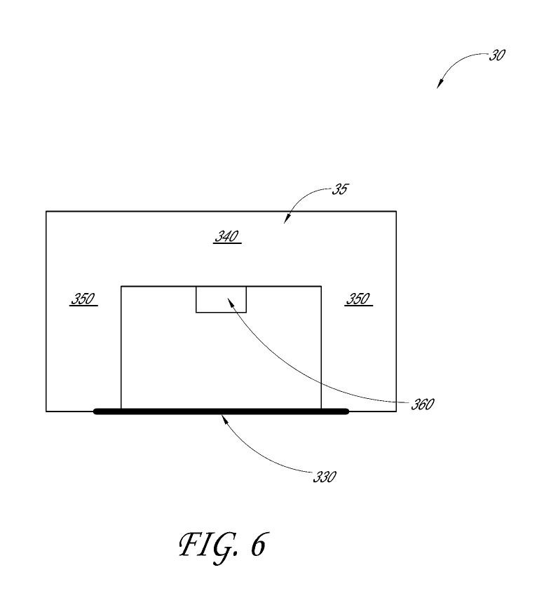

FIG. 6 schematically illustrates such an example imaging device 30 for measuring the structure of a surface in accordance with certain embodiments described herein. In certain embodiments, an imaging device 30 includes a sensor 35. The sensor 35 includes at least one sense nano-electromechanical resonator 330. The sense resonator 330 can include a nano-oscillating film 331 (within 330). As shown in FIG. 6, the sensor 35 can further include a support platform 340 having at least two support posts 350. In certain embodiments, the sense resonator 330 is suspended over a support platform 340 via support posts 350. In certain embodiments, the sensor 35 further includes a gate 360 located between two support posts 350 to actuate the film 331 of the sense resonator 330.

In certain embodiments, the nano-oscillating film 331 can include graphene as discussed above. However, a person skilled in the art would recognize that other resonating materials are possible. For example, the materials could include Aluminum Molybdenum alloys, Magnetic thin films, Piezoelectric thin films, Silicon, Gallium Arsenide, Silicon Dioxide, Graphene, Graphene Oxide, Graphite, Graphane, Silicon Carbide, Lead Selenide, Zinc Oxide, Titanium Dioxide, Vanadium Oxide, Boron Nitride, Titanium Nitride, Bismuth Selenium, Calcium Sulfide, Bismuth Oxychloride, Bismuth Vanadate, Niobium Nitride, and Niobium Oxide.

In addition, other structures are possible, for example, the structure may include a nano-beam, nano-ribbon, nano-tube, singly clamped cantilever, doubly clamped cantilever, nanowire, nano-coil, annular 2D structure, 2D rectangular structure, 2D circular structure, 2D elliptical structure, 2D hexagonal structure, 3D tetrahedral structure, 3D cylindrical structure, 3D spherical structure, 3D pyramid structure, 2D polygonal structure, etc.

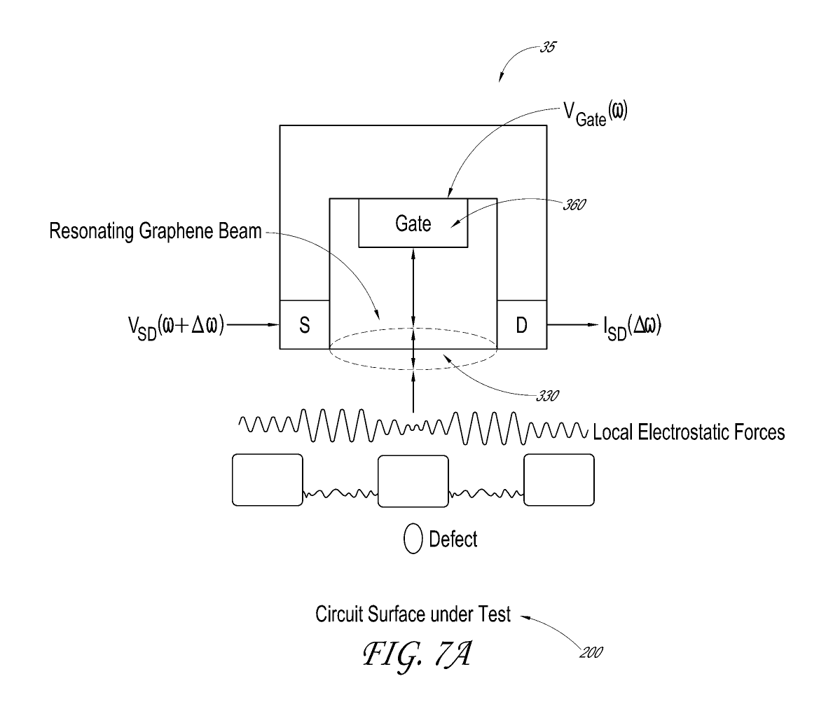

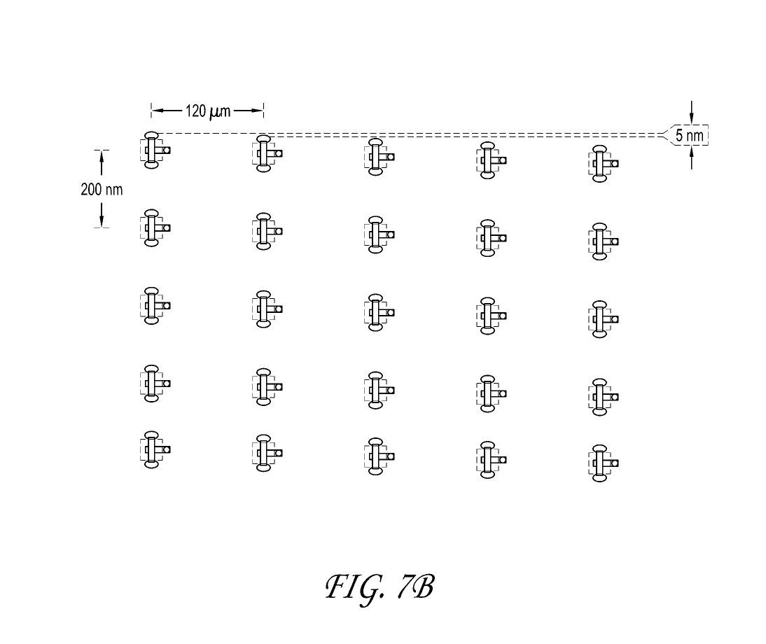

In certain embodiments, the basic operating principle for sensor 35 using an electrical readout approach is shown in FIG. 7A, where the current flowing through the sensor 35 can be mixed down to frequencies well below the cutoff. See, e.g., V. A. Sazonova, “A Tunable Carbon-Nano-Tube Resonator,” Ph.D. dissertation, Cornell University (August 2006). Considering that Z is the distance between the resonator 330 (mean reference plane of the oscillatory motion) and the gate 360, Z₀, is the initial distance, and z(ω) is the resonator's 330 amplitude of motion, then in general

Z(ω)=Z₀−z(ω)cos(ωt). (1)

Due to this motion the resonator 330-gate 360 capacitance is modulated at the frequency ω with the amplitude of

C_{gate}(ω)=(dC_{gate}/dz)z(ω). (2)

Capacitance modulation leads to charge modulation

q=C_{gate}(ω)V_{gate}=(dC_{gate}/dz)z(ω)V_{gate}^{dc} (3)

which leads to conductance modulation

G=(dG/dq)q=(dG/dq)(dC_{gate}/dz)z(ω)V_{gate}^{dc}. (4)

Hence, the conductance, and therefore current flow, through the nano-resonator 330 can be modulated at a given frequency ω.

Assuming the conductance, G, is modulated at some frequency ω as

G=G^{dc}+G cos(ωt) (5)

and assuming a local oscillator signal is applied to the source electrode at a slightly offset frequency ω+Δω then the source-drain voltage at ω+Δω is

V_{SD}^{ω+Δω}=V_{SD} cos((ω+Δω)t). (6)

The current, I, through the resonator 330 will contain both frequency components, since it depends on the source-drain voltage and the conductance of the resonator. For example,

$$\begin{matrix}I = {GV}_{SD} = ( {G}^{dc} + G cos ( ω t ) ) {V}_{SD}^{ω + Δω} \\ = {G}^{dc} {V}_{SD}^{ω + Δω} + G cos ( ω t ) {V}_{SD}^{ω + Δω} .\end{matrix} \qquad \begin{matrix}( 7 ) \\ ( 8 )\end{matrix}$$

where the first term describes the current at the local oscillator frequency and the second term consists of the product of two AC signals and responsible for the signal mixing. Expansion of the second term to isolate the contribution from the mixed signal

G cos(ωt)V_{SD} cos((ω+Δω)t)=½GV_{SD}(cos(2ωt)cos(Δωt)). (9)

showing that the amplitude of the current through the resonator, I^{Δω}, at the intermediate frequency Δω is equal to

I^{Δω}=½GV_{SD}. (10)

That is directly proportional to the conductance change of the resonator and the total current flowing through the resonator

I^{Δω}=½(dG/dq)((dC_{gate}/dz)z(ω)V_{gate}^{dc}+C_{gate}V_{gate} cos(ωt)V_{SD} cos((ω+Δω)t). (11)

Since the intermediate frequency Δω can be made arbitrarily small it is possible to make real time measurements of the high frequency conductance modulations, that otherwise could be difficult to do because of the high resonance frequency (e.g., several 100's of MHz) and large resistance typical of these devices. By directly measuring the current passing through these resonators 330 and sweeping the V_{SD} frequency, it is possible to determine the resonance frequency shift at which peak current flows attributable to a change in tension induced by coupling of the nano-resonator materials with the local atomic forces and fields of the SUT as the sensor 35 is being scanned across.

Changes in resonator tension via coupled interactions with the local environment can induce amplitude, phase, and frequency variations. By measuring the amount of resonance shift either by mechanical monitoring strain, optical monitoring of surface deformation due to perturbations in the oscillations of the resonator, or electrically monitoring the resonance shift in peak current provides a means for sensing the magnitude of the local environmental interaction. Calibration of the response of the NEMS sensor to known structural features allows a means to reconstruct the surface of an arbitrary sample similar to the methods used for AFM instrumentation.

For mechanical resonators under a given beam tension T, the fundamental resonance mode f₀ for a clamped-clamped free standing beam is given by

f₀={square root over ((A\sqrt{(E/ρ)}(τ/L²)²)+(0.57A²S/ρL²τ))} (12)

where E is the Young's modulus, S is the tension per unit width, ρ is the mass density, τ and L, are the thickness and length of the suspended graphene beam, and A is a geometric scaling factor equal to 1.03 for doubly-clamped beams. See, e.g., J. S. Bunch, “Mechanical and Electrical Properties of Graphene Sheets,” Ph.D. dissertation, Cornell University (May 2008).

In certain embodiments, high local resolution can be attained with high curvature of the nano-resonator design. Electromechanical actuation is a convenient method to excite the resonators. However, the electrostatic force is attractive and nonlinear, resulting in an event known as “pull-in.” See, e.g., P. M. Osterberg and S. D. Senturia, “M-TEST: a test chip for MEMS material property measurement using electrostatically actuated test structures,” J. of Micromechanical Systems, Vol. 6, No. 2, pp. 107-118 (1997). Under static conditions, the deflection increases to one third of the initial gap at pull-in, and then the beam force can no longer overcome the electrostatic force, resulting in beam collapse and an electrical short. Fortunately, under resonant conditions, it is possible to attain stable dynamic deflections about the neutral-plane with an amplitude equal to the full gap. See, e.g., G. N. Nielsen et al., “Dynamic pull-in of parallel-plate and torsional electrostatic MEMS actuators,” J. of Micromechanical Systems, Vol. 15, No. 4, pp. 811-821 (2006). Furthermore, with high Q, this amplitude can be achieved at voltages much lower than the static pull-in voltage. As an estimate to zeroth order, at maximum beam deflection the first order mode beam shape will be v(x)=(g/2)·(1−cos(2πx/L)), where g is the gap for electrostatic actuation and L is the beam length. This function is maximum at x=0.5 L, and reduces by 10% for x=0.4 L or x=0.6 L. Because surface forces are generally proportional to d⁻³, where d is the separation between planar objects, the resolution of certain embodiments along the length of the beam can be approximately 0.2 L, or 20 nm if L=100 nm.

Certain embodiments disclosed herein advantageously include a plurality of sensors 35. For example, in certain embodiments, an image head having an array of sensors 25 is designed to provide high image resolution with significant reduced data acquisition time and improved reliability and measurement sensitivity compared to current state-of-the-art diagnostic tools for imaging large specimen areas, e.g., about 1 cm², for example on the surface of a processed wafer. FIG. 7B shows one embodiment of the sensors 35 in an array. The sensors 35 could be of a single resonator architecture type as discussed above. In other embodiments, the sensors 35 used in the patterned array could include other resonator architecture types. In certain embodiments, the sensors 35 could be configured in multiple geometric orientation along a 2D plane or in multiple geometric orientation along the axial 3D coordinate. In certain embodiments, as will be described below, the plurality of sensors 35 is advantageously arranged in a staggered configuration.

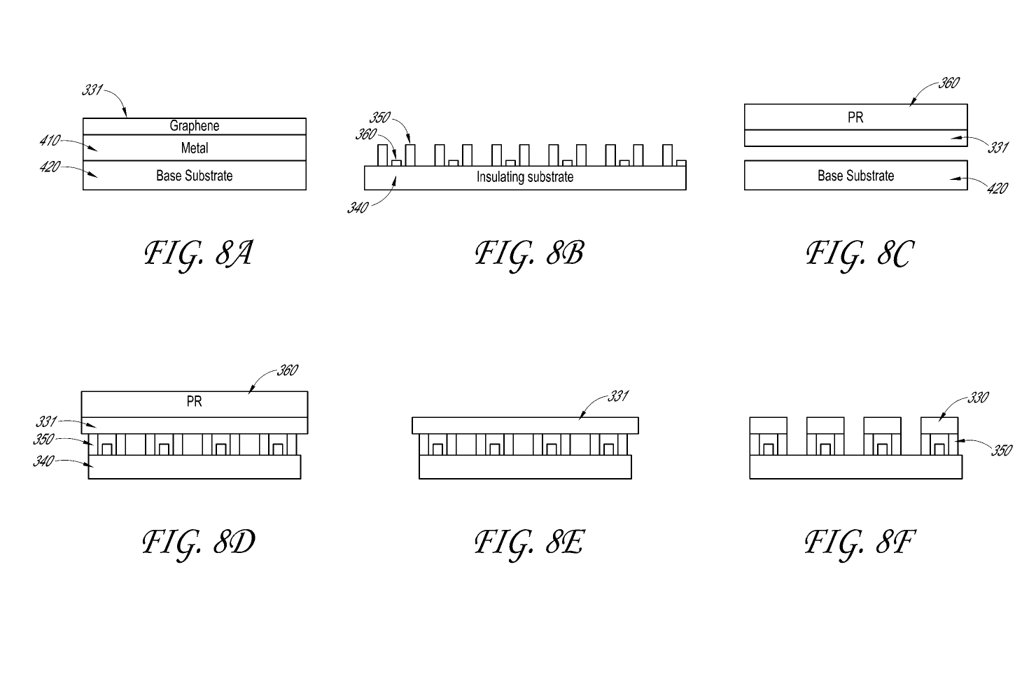

FIGS. 8A-8F schematically illustrate an example method to produce at least one sensor 35 or an array of sensors 35. FIGS. 8A-8F use graphene-based nano-oscillating film as an example. However, as discussed above, other materials and structures are possible. To produce certain embodiments of the sensor 35, a support platform 340 onto which the film 331, e.g., graphene film, can be transferred is advantageous to anchor the film 331, as well as to provide electrical contacts for electrical readout. In certain embodiments, the support platform 340 includes support posts 350 fabricated in an array. These posts 350 can act as anchor points for the clamped-clamped resonators 330. Pairs of posts 350 can be located, e.g., about 100 nm apart and be, e.g., about 200 nm high. A thinner gate electrode 360 can be located between the support posts 350 in certain embodiments and used for RF actuation of the graphene beam 331.

In the embodiment of the nano-resonator fabrication process shown in FIGS. 8A-8E, a graphene sequence array is produced. The first step, as shown in FIG. 8A, can include graphene 331 synthesis on SiN or metal 410 on a base or growth substrate 420. The second step, as shown in FIG. 8B, can include the fabrication of the support platform 340 using e-beam lithography. Next, as shown in FIGS. 8C and 8D, the graphene film 331 can be released from the base or growth substrate 420 and transferred to the support platform 340. In certain embodiments, this is advantageous since the substrate 420, on which the graphene 331 was grown, may not be suitable for the types of processing used to create clamped-clamped graphene beams 331.

To transfer the graphene 331, approaches that have been previously reported in the literature or yet to be devised can be used. See, e.g., A. Reina et al., “Large Area, Few-Layer Graphene Films on Arbitrary Substrates by Chemical Vapor Deposition,” Nano Letters, Vol. 9, No. 1, pp. 30-35 (2009); K. S. Kim et al., “Large-scale pattern growth of graphene films for stretchable transparent electrodes,” Nature, Vol. 457, p. 706-710 (2009); and W. Liu et al., “Chemical vapor deposition of large area few layer graphene on Si catalyzed with nickel film,” Thin Solid Films, Vol. 518, No. 6, pp. S128-S132 (2010). One possible approach, as shown in FIG. 8C, consists of placing a polymer, such as a photoresist (PR) 360, over a graphene film 331 that has been synthesized on a metal surface 410. Once coated with PR 360, the metal 410 is then etched, releasing the graphene film 331/PR 360 from the growth substrate 420. Now the PR 360 can act as a manipulation handle, allowing the graphene film 331 to be positioned over the support platform 340. Once the graphene film 331 is in position, the PR 360 can be removed using a solvent rinse as shown in FIG. 8E. Post transfer, the final steps can involve using digital beam processing (DBP) with a modified Focused Ion Beam (FIB) tool to pattern the individual resonators 330 and make ohmic contact to the underlying metal support posts 350 as shown in FIG. 8F.

In terms of DBP development, over the past few years, it has demonstrated that a new family of ion beam etching techniques, ideal for high resolution, high throughput, microelectronics manufacturing (using a resistless assisted multi-activation FIB process), has a lot of benefits. This new process family is called ion beam assisted chemical etching (IBACE), and can be 10 to 100 times more sensitive to ion exposure than the milling technique. It is a two-step process that uses FIB to pattern the etched regions. Only the target surface is exposed to very low dose ion exposure, creating a reactive region for the chemical agent. The wafer is introduced to the reactive gas within a separate corrosive hardened chamber. As a result, a high-resolution dry chemical etching process actively removes the material within the desired location as a parallel process to exposure. IBACE can be performed on silicon, silicon dioxide with Cl or F gas, GaAs with Cl gas, diamond with O₂ and N₂O₃, tungsten, graphene, and molybdenum with CBrF₃, and high temperature superconducting ceramics with wet hydroxide chemicals (NaOH, KOH)—all done outside of the vacuum system. The technique has been successfully applied to etching the gate recess of GaAs FET devices without destroying the underlying active device region. IBACE GaAs FET IBACE process recess etch provides a unique control and uniformity unlike any other etch processes as seen by the 15×15 emission tips. DBP etching provides high-resolution removal of-material without the use of resist.

In certain embodiments, the sensing method of profiling the surface 200 uses electrical readout. Minute changes in local electrostatic forces are sensed via interactions with each nano-resonator 330 due to local variations in the circuit surface 200 being measured that modify the tension and the corresponding resonant frequency shifts. The conductivity of the nanoresonator increases significantly near the resonant frequency (see, e.g., J. S. Bunch, “Mechanical and Electrical Properties of Graphene Sheets,” Ph.D. dissertation, Cornell University (May 2008), resulting in a sharply-defined current peak for a given input voltage.

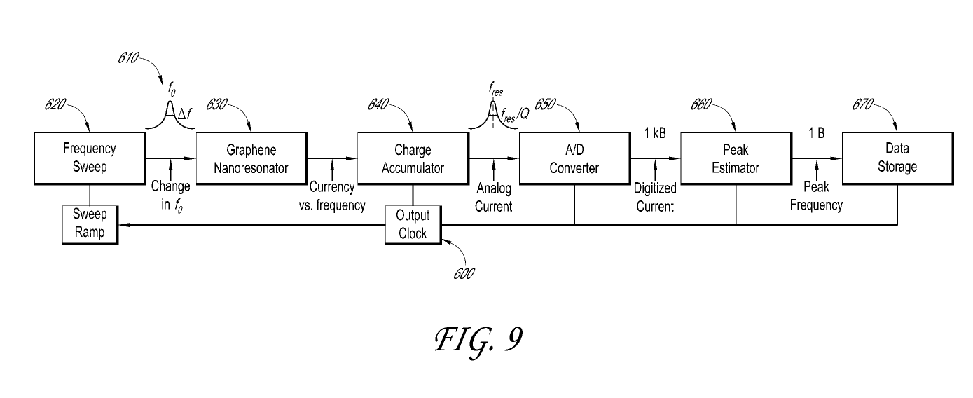

An example measurement system is shown in FIG. 9. Other measurement systems are possible. For this example measurement system, a master clock 600 can control all the measurements. A sinusoidal frequency 610 is generated, with a constant bandwidth Δf, but a swept center frequency f₀ using a broadband RF source. This center frequency is swept rapidly from the minimum frequency of interest, f_{low}, to the maximum frequency of interest, f_{high}. The charge accumulator 640 in the electronic readout chain integrates the current passing through the nanoresonator 630 for a time interval specified by the output clock 600, then dumps the current to the A/D converter 650 and resets itself. The output of the accumulator 640 is a voltage linearly proportional to the product of the accumulation time with the average current amplitude over that time. This voltage is digitized in the A/D converter 650. The stream of data corresponding to the frequency sweep can be about 1 kB. A peak estimator 660 can be used to calculate the frequency at which the current—and thus the conductivity—is greatest. This can be digitized to 1 byte of data, producing an estimated peak frequency with resolution (f_{high}−f_{low})/256. The resulting data can be 1 byte of storage for every pixel measured. Based on 5-nm resolution in a 1×1 cm square, there can be 4 TB of data in one image. (This is approximately the same amount of data in one hour of high-definition television.)

In certain embodiments, the frequency sweep 620 can be produced by a commercial frequency generator such as the Agilent E8663D-007. The minimum sweep time of this generator can be 1 ms, although it can be gated and can scan at 25 MHz/μs. The frequency sweep can be applied as an input signal to all the resonators 630 simultaneously. Accordingly, the longest electrical path length difference between pixels can be 4.785 mm. Assuming an electrical propagation speed ⅓ the speed of light, the difference in signal propagation time to all pixels can be <48 ps. This is nearly four orders of magnitude less than the minimum sampling time, so it does not have any effect on the measurements in this embodiment. In certain embodiments, the PCB layout has a rectifier, the gated charge accumulator 640, and the A/D converter 650 all fabricated directly on the scan head. Digital data can then be read out at the interface. This data can then be processed by the peak estimators 660, and the output of these estimators can be sent to data storage 670, e.g., commercial RAM, for storage and display. The information can then be stored, as needed, on a hard drive or in other non-volatile memory. In certain embodiments, the peak estimators 660 can be built into the scan head as well.

The analog input to the A/D converter 650 on the imaging head produces a byte of data for each sample. Each byte describes the current corresponding to a single frequency value for that particular resonator. The string of bytes generated in a single frequency sweep are collected; this string is passed to a peak estimator circuit. The output of the peak estimator circuit is a one-byte value describing the estimated position of the peak (in digital order). This position is correlated to the resonant frequency by a simple scale factor. Thus, the analog current measured by each pixel, over the time of a frequency sweep, produces a single byte describing the resonant frequency of the resonator—and thus the force on the resonator. Further each pixel is measured and processed individually, resulting in 20 kB of data for each location of the scan head. These are read out and stored in the memory locations corresponding to their pixel location.

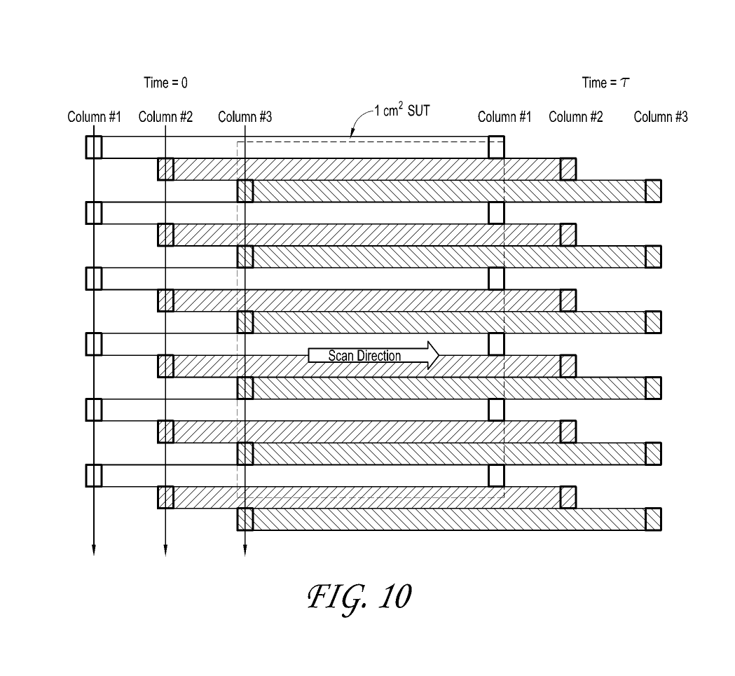

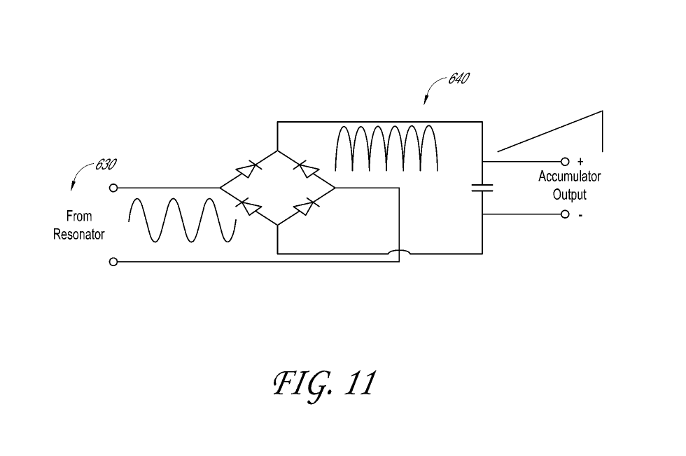

An example embodiment of a scan head configuration is shown in FIG. 10. In this embodiment, the plurality of resonators 330 is arranged in a staggered configuration. The location of each sensor in a column is staggered from the position of the sensors in an adjacent column by an amount equal to the desired image pixel resolution. In operation the image head is positioned using a precision XYZ stage in such a way that the N^{th} column of sensors is at the left most edge of the SUT. The image head is then scanned over the SUT so that each column of sensors passes over the entire area of the SUT. In this way when the 1^{st} column of sensors travels past the same area previously measured in time by the N^{th} column of sensors, the full data set collected from each sensor column which was stored can then be processed and collapsed into a single line of the SUT image. Initially there can be a data lag (time it takes for the 1^{st} column to move to the initial starting position of the N^{th} column) because the scan head in operation can be positioned prior to the start of the image scan so that the leftmost edge of the N^{th} column is aligned to sub-nm precision with the leftmost edge of the SUT. Certain embodiments can be used with high precision commercial state-of-the-art 3-axis stages that can provide both lateral and depth accuracy.

In one embodiment the orientation of the long axis for each column of sensors is perpendicular to the scan direction. In another embodiment the long axis is rotated to form an arbitrary angle with the scan direction. In another embodiment the orientation of the long axis of each sensor within a column of the array is rotated relative to each adjacent row within the column.

As an example, the imaging device circuit can be composed of 512 columns of resonators spaced on 200-nm centers perpendicular to the scan direction, and 40 rows of resonators spaced on 120-μm centers along the scan direction. The spacing along the scan direction allows for 20 nm traces to provide connection from the drive and readout electronic interfaces to the devices. The topmost edge of each new column of resonators is also staggered from the adjacent column downward by 5 nm, so that the 40^{th} row is 195 nm offset from the first. This array layout defines the sampling pixel size as 5 nm².

Since the imaging device image pixel size depends in certain embodiments on both the resonator width and offset position of the columns relative to each other, this approach is scalable to meet the resolution requirements of interest. Additional sensor columns and narrower width resonators leads to smaller image pixel sizes. Since the main region of influence of environmental electrostatic forces on an individual resonator can be in close proximity to its center in certain embodiments, the sampling size of each resonator has an effective width of 5 nm along the scan direction. For example, in an embodiment with a staggered configuration, the centers of the resonators are advantageously closer together as compared to resonators abutting one another.

To acquire the full image of the surface under test (SUT) the scan rate (in the direction of the 120-μm spacing) used to allow ample time for the readout electronics is 5 μm/s, so that the movement of a single column of sensors a distance equivalent to the 5 nm width uses 1 ms, or 40× the single frequency sweep time. Thus, a single frequency scan encompasses 125 pm of motion, ensuring that it is, in effect, a single point measurement. Moreover the current measurement values collected from each sensor of the array is data logged along with the X and Y location of the sensor relative to the wafer stage reference origin.

In this embodiment, when the 1^{st} column of sensors travels past the same area previously measured in time by the 40^{th} column of sensors, the full data set collected from each sensor column that passed over this same area and stored can be collapsed into a single line of the SUT image. Then every 1 ms thereafter, the next line of the image can be processed and so on until the full 1 cm² SUT has been measured and displayed.

Assuming the measurement sweep takes 20 μs per each frequency, and there are 50 frequency bins to sample, then the total time available for one full set of frequency measurements is 1 ms. If the stage the imaging device scan head is mounted to is moving (without slipping) at a slow rate of 5 μm/s then the total distance the imaging device scan head has moved during this time interval is 5 nm. So each full frequency sweep samples a 5 nm distance. Assuming the imaging device scan head has to move a total of 2 cm (from initial position of scan head to final position of scan head) to have sufficient overlap of all the sensor columns to form an image of the central SUT area then requires 4×10⁶ such measurements of 5 nm step. The total time for the complete scan of the sensor array is therefore 4000 seconds! As this example shows, certain embodiments disclosed herein can dramatically reduce the overall image acquisition time.

In certain embodiments, the entire 1 cm² area can generate 4 Tpx at 1 byte each, or 4 TB of data. In 1 ms, the data output can be 20 kB, the output from a single set of scans; the data rate, then, is low, 20 MB/s (USB can transfer 60 MB/s). To get this data, however, several steps can be utilized. In certain embodiments, it can be advantageous to study the availability of converters. It is possible to increase the accumulated charge by increasing the accumulation time (and decreasing the frequency sweep rate). The maximum time available for a single frequency sweep is ˜500 μs, which corresponds to 2.5 nm of motion, without adding pixel crosstalk to the system. This corresponds to charge collection of 5.42×10⁻¹⁴ C, or 338,000 electrons collected. The analog charge accumulator 640 of FIG. 9 can include a rectifier to ensure maximum collection. In certain embodiments, the circuit of the charge accumulator 640 is shown in FIG. 11. The sinusoidal signal is first rectified then its charge is collected on a capacitor. The voltage on the capacitor, proportional to its charge, increases almost linearly until it is read out to the A/D converter 650, discharging the capacitor.

In certain embodiments, the analog input to the A/D converter 650 (most likely a flash converter, since there is enough space on the scan head to fit the accumulator and a flash A/D converter between the columns of resonators) produces a byte of data for each sample. Each byte describes the current corresponding to a single frequency value at that resonator 630. The string of bytes generated in a single frequency sweep is collected; this string is passed to a peak estimator 660 circuit. The output of the peak estimator 660 circuit is a one-byte value describing the estimated position of the peak (in digital order). This position is correlated to the resonant frequency by a simple scale factor. Thus, the analog current measured by each pixel, over the time of a frequency sweep, produces a single byte describing the resonant frequency of the resonator 630—and thus the force on the resonator 630. The precise relationship between this force and the surface profile can be determined. Further, each pixel is measured and processed individually, resulting in 20 kB of data for each location of the scan head. These are read out and stored in the memory locations of the data storage 670 corresponding to their pixel location.

In certain embodiments, while each column of pixels is offset by 5 nm with respect to the previous column, each resonator is, e.g., about 100 nm long. Thus, some crosstalk or blurring can occur even though the strongest effect on the resonator can be at the center of the strip (e.g., about 50 nm from the anchors), the surface profile along the entire 100 nm contributes to the overall tension of the nano-oscillating strip—and thus to the resonant frequency of the resonator. Standard image processing techniques can be used to reduce this crosstalk. Studying this effect and determining if the unusual conductivity pattern of materials such as graphene—which results in the conductivity varying with distance to the electrodes—can be used to help reduce pixel crosstalk during the data extraction process.

The 4 TB of data can be 4 Tpx, each corresponding to a 5 nm square inside the 1 cm square test area. Any portion of this can be displayed. In certain embodiments, since the data cover 2,000,000×2,000,000 locations, and the highest resolution display screen in common use is 2560×1440, the highest zoom level is 800×, covering an area 12.8 μm wide and 7.2 μm high.

Although this invention has been disclosed in the context of certain preferred embodiments and examples, it will be understood by those skilled in the art that the present invention extends beyond the specifically disclosed embodiments to other alternative embodiments and/or uses of the invention and obvious modifications and equivalents thereof. In addition, while several variations of the invention have been shown and described in detail, other modifications, which are within the scope of this invention, will be readily apparent to those of skill in the art based upon this disclosure. It is also contemplated that various combinations or sub-combinations of the specific features and aspects of the embodiments may be made and still fall within the scope of the invention. It should be understood that various features and aspects of the disclosed embodiments can be combined with, or substituted for, one another in order to form varying modes of the disclosed invention. Thus, it is intended that the scope of the present invention herein disclosed should not be limited by the particular disclosed embodiments described above, but should be determined by a fair reading of the claims that follow.

What is claimed is:

1. An imaging device for measuring a structure of a surface, the device comprising:
at least one nano-mechanical resonator pair comprising:
a reference resonator having a reference resonant frequency, and
a sense resonator having a first sense resonant frequency,
wherein the device is configured to expose the sense resonator to the surface such that the sense resonator has a second sense resonant frequency, and wherein the device is configured to measure the structure of the surface based on a difference between the second sense resonant frequency and the reference resonant frequency.

2. The device of claim 1, wherein the at least one nano-mechanical resonator pair comprises a plurality of nano-mechanical resonator pairs.

3. The device of claim 1, further comprising an array of reference resonators.

4. The device of claim 1, further comprising an array of sense resonators.

5. The device of claim 4, wherein the array is configured in multiple geometric orientation along a 2D plane.

6. The device of claim 4, wherein the array is configured in multiple geometric orientation along an axial 3D coordinate.

7. The device of claim 1, wherein the sense resonator is displaced along the surface over time while scanning.

8. The device of claim 1, wherein the reference resonator comprises a reference nanomechanical structure and the sense resonator comprises a sense nanomechanical structure.

9. The device of claim 8, wherein at least one of the reference nanomechanical structure or the sense nanomechanical structure comprises a ribbon, an annular 2D structure, a 2D rectangular structure, a 2D hexagonal structure, a 2D circular structure, a 3D spherical structure, a 3D pyramid structure, or a 3D tetrahedral structure.

10. The device of claim 4, wherein each sense resonator comprises a sense nanomechanical structure, and at least of the sense nanomechanical structures have different nanomechanical structure.

11. The device of claim 8, wherein at least one of the reference nanomechanical structure or the sense nanomechanical structure comprises a physical structure.

12. The device of claim 8, wherein at least one of the reference nanomechanical structure or the sense nanomechanical structure comprises a mini structure.

13. The device of claim 8, wherein at least one of the reference nanomechanical structure or the sense nanomechanical structure comprises at least one of graphene, aluminum molybdenum alloys, Magnetic thin films, Piezoelectric thin films, Silicon, Gallium Arsenide, Silicon Dioxide, Graphene Oxide, Graphite, Graphane, Silicon Carbide, Lead Selenide, Zinc Oxide, Titanium Dioxide, Vanadium Oxide, Boron Nitride, Titanium Nitride, Bismuth Selenium, Calcium Sulfide, Bismuth Oxychloride, Bismuth Vanadate, Niobium Nitride, or Niobium Oxide.

14. The device of claim 8, wherein at least one of the reference nanomechanical structure or the sense nanomechanical structure is suspended over a trench on a substrate and clamped on at least two ends.

15. The device of claim 8, wherein the reference nanomechanical structure and the sense nanomechanical structure are excited such that the first sense resonant frequency is substantially the same as the reference resonant frequency.

16. The device of claim 8, wherein the reference nanomechanical structure and the sense nanomechanical structure are excited by at least one of a laser, an electric field, a gravitational field, a phonon, a magnetic field, light, temperature, or physical contact.

17. The device of claim 1, wherein the device is configured to isolate the reference resonator from the surface and to expose the sense resonator to a force at the surface.

18. The device of claim 17, wherein the second sense resonant frequency results from the force applied to the sense resonator.

19. The device of claim 18, wherein the applied force is derived from at least one of an electric field, a gradational field, phonons, a magnetic field, light, temperature, or physical contact.

20. The device of claim 1, further comprising a laser interferometer to measure the difference between the second sense resonant frequency and the reference resonant frequency.

21. The device of claim 20, wherein the laser interferometer transmits a first light incident on the reference resonator and a second light incident on the sense resonator.

22. The device of claim 21, wherein the reference resonator is configured to reflect a portion of the first light, the portion of the first light having a first phase and a first optical path; and the sense resonator is configured to reflect a portion of the second light, the portion of the second light having a second phase and a second optical path.

23. The device of claim 22, wherein the laser interferometer records an interference pattern, the interference pattern being a combination of the reflected portion of the first light and the reflected portion of the second light.

24. The device of claim 23, wherein the laser interferometer records the interference pattern at a different wavelength than used to excite the resonators.

25. The device of claim 22, wherein the difference between the second sense resonant frequency and the reference resonant frequency is measured by measuring a difference between the second phase and the first phase.

26. The device of claim 22, wherein the difference between the second sense resonant frequency and the reference resonant frequency is measured by measuring a difference between the second optical path and the first optical path.

27. The device of claim 1, further comprising an electrical measurement difference between the second sense resonant frequency and the reference resonant frequency.

28. The device of claim 27, wherein a first electrical excitation signal is applied on the reference resonator and a second electrical signal on the sense resonator.

29. The device of claim 28, wherein the device is configured to compare a portion of the first electrical signal, the portion of the first signal having a first phase and a first amplitude; with a portion of the second signal, the portion of the second signal having a second phase and a second amplitude.

30. The device of claim 29, wherein the device records a Lissajous figure pattern, the pattern being a combination of the phases and amplitudes.

31. The device of claim 30, wherein the difference between the second sense resonant frequency and the reference resonant frequency is measured by measuring a difference between the second phase and the first phase.

32. The device of claim 30, wherein the difference between the second sense resonant frequency and the reference resonant frequency is measured by measuring a difference between the second amplitude and the first amplitude.

33. The device of claim 1, wherein the resolution is between the range of about 1-100 nm, about 0.1-10 nm, about 0.1-5 nm, about 2-3 nm, or about 0.1-1 nm.

34. The device of claim 1, wherein the sensitivity is about 100 pico-Newtons, about 10 pico-Newtons, about 1 pico-Newtons, or about 0.1 pico-Newtons.

35. A method for measuring a structure of a surface comprising:
providing at least one nano-mechanical resonator pair comprising:
a reference resonator having a reference resonant frequency, and
a sense resonator having a first sense resonant frequency;
exposing the sense resonator to the surface such that the sense resonator has a second sense resonant frequency; and
measuring a difference between the second sense resonant frequency and the reference resonant frequency.

36. A method for fabricating an imaging device for measuring a structure of a surface comprising:
providing at least one nano-mechanical resonator pair comprising:
providing a reference resonator comprising:
providing a reference nanomechanical structure,
suspending the reference nanomechanical structure over a trench on a substrate, and
clamping the reference nanomechanical structure on at least two ends, and
providing a sense resonator comprising:
providing a sense nanomechanical structure,
suspending the sense nanomechanical structure over a trench on a substrate, and
clamping the sense nanomechanical structure on at least two ends; and
tuning the reference nanomechanical structure and the sense nanomechanical structure, such that the reference resonator has a reference resonant frequency and the sense resonator has a first sense resonant frequency; wherein the device is configured to expose the sense resonator to the surface such that the sense resonator has a second sense resonant frequency, and wherein the device is configured to measure the structure of the surface based on a difference between the second sense resonant frequency and the reference resonant frequency.
